(19) United States
(12) Patent Application Publication
(10) Pub. No.: US 2026/0107571 A1
(43) Pub. Date: Apr. 16, 2026

(54) SEMICONDUCTOR DEVICE AND MANUFACTURING METHOD THEREOF

(71) Applicant: INSTITUTE OF MICROELECTRONICS, CHINESE ACADEMY OF SCIENCES, Beijing (CN)

(72) Inventors: Yongliang LI, Beijing (CN); Huaizhi LUO, Beijing (CN); Xiaolei WANG, Beijing (CN); Jun LUO, Beijing (CN)

(21) Appl. No.: 19/277,635

(22) Filed: Jul. 23, 2025

(30) Foreign Application Priority Data
Oct. 16, 2024 (CN) 202411449225.5

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

The semiconductor device includes a base substrate, first and second layer semiconductor structures, first and second contact structures. The second layer semiconductor structure is arranged above the first layer semiconductor structure at intervals along a thickness direction of the base substrate. The first contact structure is arranged in the base substrate and includes a first contact portion in electrical contact with a first source/drain region included in the transistor in the first layer semiconductor structure and a second contact portion in electrical contact with a first gate stack structure. The second contact structure is arranged on a side of the second layer semiconductor structure away from the first layer semiconductor structure and includes a third contact portion in electrical contact with a second source/drain region included in the transistor in the second layer semiconductor structure and a fourth contact portion in electrical contact with a second gate stack structure.

### CROSS-REFERENCE TO RELATED APPLICATION

This application claims the priority of Chinese Patent Application No. 202411449225.5 filed on Oct. 16, 2024 in the China National Intellectual Property Administration, the content of which is incorporated herein by reference in entirety.

### TECHNICAL FIELD

The present disclosure relates to a technical field of semiconductors, and in particular to a semiconductor device and a manufacturing method thereof.

### BACKGROUND

Interconnection technology of integrated circuits is a crucial and necessary part of packaging. Specifically, the interconnection technology of integrated circuits is a technology of connecting independent components in the same chip into a circuit module with certain functions in a certain manner, and is of high importance in advanced packaging. Chips are interconnected by packaging to receive power, exchange signals and finally perform operations. Since the speed, density and function of semiconductor products change according to the interconnection manner, the interconnection method is constantly changing and developing.

However, with the miniaturization of the device size, after the independent components in an existing semiconductor device are interconnected, the problem of signal line congestion is easy to occur, resulting in poor voltage drop and low working performance of the semiconductor device.

### SUMMARY

The present disclosure provides a semiconductor device. The semiconductor device includes: a base substrate, a first layer semiconductor structure, a second layer semiconductor structure, a first contact structure, and a second contact structure. The first layer semiconductor structure is arranged on the base substrate. The second layer semiconductor structure is arranged above the first layer semiconductor structure at intervals along a thickness direction of the base substrate, in which the first layer semiconductor structure and the second layer semiconductor structure each include a plurality of transistors distributed at intervals along a direction perpendicular to the thickness direction of the base substrate. The first contact structure is arranged in the base substrate and includes a first contact portion in electrical contact with a first source/drain region included in the transistor in the first layer semiconductor structure and a second contact portion in electrical contact with a first gate stack structure included in at least some of the transistors in the first layer semiconductor structure, in which the first contact portion and the second contact portion are insulated from each other. The second contact structure is arranged on a side of the second layer semiconductor structure away from the first layer semiconductor structure and includes a third contact portion in electrical contact with a second source/drain region included in the transistor in the second layer semiconductor structure and a fourth contact portion in electrical contact with a second gate stack structure included in at least some of the transistors in the second layer semiconductor structure, in which the third contact portion and the fourth contact portion are insulated from each other.

In one exemplary embodiment, a contact manner between the first contact portion and the first source/drain region is a direct backside contact.

In one exemplary embodiment, the contact manner between the second contact portion and at least part of the first gate stack structure is the direct backside contact.

In one exemplary embodiment, the first contact portion is in self-alignment with the first source/drain region.

In one exemplary embodiment, the semiconductor device further includes a dielectric sidewall located between the first contact portion and the second contact portion, and located below a first gate sidewall of at least some of the transistors in the first layer semiconductor structure.

In one exemplary embodiment, an end portion of the first contact portion away from the second layer semiconductor structure, an end portion of the second contact portion away from the second layer semiconductor structure and an end portion of the dielectric sidewall away from the second layer semiconductor structure are aligned.

In a second aspect, the present disclosure provides a manufacturing method of a semiconductor device. The manufacturing method of a semiconductor device includes: first, forming a first layer semiconductor structure and a base substrate, in which the first layer semiconductor structure is arranged on the base substrate; then, forming a first contact structure in the base substrate; next, forming a second layer semiconductor structure arranged above the first layer semiconductor structure at intervals along a thickness direction of the base substrate, in which the first layer semiconductor structure and the second layer semiconductor structure each include a plurality of transistors distributed at intervals along a direction perpendicular to the thickness direction of the base substrate, the first contact structure includes a first contact portion in electrical contact with a first source/drain region included in the transistor in the first layer semiconductor structure and a second contact portion in electrical contact with a first gate stack structure included in at least some of the transistors in the first layer semiconductor structure, and the first contact portion and the second contact portion are insulated from each other; and subsequently, forming a second contact structure arranged on a side of the second layer semiconductor structure away from the first layer semiconductor structure, in which the second contact structure includes a third contact portion in electrical contact with a second source/drain region included in the transistor in the second layer semiconductor structure and a fourth contact portion in electrical contact with a second gate stack structure included in at least some of the transistors in the second layer semiconductor structure, and the third contact portion and the fourth contact portion are insulated from each other.

In one exemplary embodiment, the forming a first layer semiconductor structure includes: providing a semiconductor substrate; then, forming a plurality of fin structures distributed at intervals along the direction perpendicular to the thickness direction of the base substrate on the semiconductor substrate, and a mask structure spanning across the fin structures; next, selectively removing a portion of each of the fin structures exposed outside the mask structure; subsequently, selectively etching, under a protective effect of the mask structure, a part of the semiconductor substrate to form a first open slot and a preformed structure filled in the first open slot, in which a material of the preformed structure is different from a material of the semiconductor substrate; afterwards, forming the first source/drain region above the preformed structure; and then, forming, based on rest of the fin structures, a first channel region included in the transistor in the first layer semiconductor structure and the first gate stack structure on a periphery of the first channel region.

In one exemplary embodiment, the forming a base substrate and a first contact structure includes: selectively removing the semiconductor substrate; then, forming the base substrate on a side of the first layer semiconductor structure away from the second layer semiconductor structure, in which the base substrate is flush with a side of the preformed structure away from the first layer semiconductor structure, and a material of the base substrate is different from a material of the preformed structure; next, selectively removing the preformed structure, and forming the first contact portion in the first open slot; subsequently, selectively removing a portion of the base substrate below the first gate stack structure to form a second open slot; and afterwards, forming a dielectric sidewall at least covering a side wall of the first contact portion in the second open slot and along a length direction of the first gate stack structure, and the second contact portion in rest of the second open slot to obtain the first contact structure.

In one exemplary embodiment, the material of the preformed structure includes at least one of silicon nitride, silicon oxynitride or amorphous carbon.

In one exemplary embodiment, after the second layer semiconductor structure arranged above the first layer semiconductor structure at intervals is formed along the thickness direction of the base substrate, the base substrate is formed, and the first contact structure is formed in the base substrate.

### BRIEF DESCRIPTION OF THE DRAWINGS

The accompanying drawings illustrated here are used to provide a further understanding of the present disclosure and constitute a part of the present disclosure. The illustrative embodiments of the present disclosure and the descriptions thereof are used to explain the present disclosure and do not constitute an undue limitation of the present disclosure. In the accompanying drawings:

Parts (1) and (2) in FIG. 1 are respectively schematic structural diagrams 1 and 2 of a semiconductor device provided by the embodiments of the present disclosure in a manufacturing process;

Parts (1) and (2) in FIG. 2 are respectively schematic structural diagrams 3 and 4 of a semiconductor device provided by the embodiments of the present disclosure in a manufacturing process;

Parts (1) and (2) in FIG. 3 are respectively schematic structural diagrams 5 and 6 of a semiconductor device provided by the embodiments of the present disclosure in a manufacturing process;

Parts (1) and (2) in FIG. 4 are respectively schematic structural diagrams 7 and 8 of a semiconductor device provided by the embodiments of the present disclosure in a manufacturing process;

Parts (1) and (2) in FIG. 5 are respectively schematic structural diagrams 9 and 10 of a semiconductor device provided by the embodiments of the present disclosure in a manufacturing process;

Parts (1) and (2) in FIG. 6 are respectively schematic structural diagrams 11 and 12 of a semiconductor device provided by the embodiments of the present disclosure in a manufacturing process;

Parts (1) and (2) in FIG. 7 are respectively schematic structural diagrams 13 and 14 of a semiconductor device provided by the embodiments of the present disclosure in a manufacturing process;

FIG. 8 is a schematic structural diagram 15 of a semiconductor device provided by the embodiments of the present disclosure in a manufacturing process;

FIG. 9 is a schematic structural diagram 16 of a semiconductor device provided by the embodiments of the present disclosure in a manufacturing process;

FIG. 10 is a schematic structural diagram 17 of a semiconductor device provided by the embodiments of the present disclosure in a manufacturing process;

FIG. 11 is a schematic structural diagram 18 of a semiconductor device provided by the embodiments of the present disclosure in a manufacturing process;

FIG. 12 is a schematic structural diagram 19 of a semiconductor device provided by the embodiments of the present disclosure in a manufacturing process;

FIG. 13 is a schematic structural diagram 20 of a semiconductor device provided by the embodiments of the present disclosure in a manufacturing process;

FIG. 14 is a schematic structural diagram 21 of a semiconductor device provided by the embodiments of the present disclosure in a manufacturing process;

FIG. 15 is a schematic structural diagram 22 of a semiconductor device provided by the embodiments of the present disclosure in a manufacturing process;

FIG. 16 is a schematic structural diagram 23 of a semiconductor device provided by the embodiments of the present disclosure in a manufacturing process;

FIG. 17 is a schematic structural diagram 24 of a semiconductor device provided by the embodiments of the present disclosure in a manufacturing process.

Reference signs: 11 Base substrate, 12 First layer semiconductor structure, 13 Second layer semiconductor structure, 14 Transistor, 15 First contact structure, 16 First contact portion, 17 Second contact portion, 18 First source/drain region, 19 First gate stack structure, 20 Second contact structure, 21 Third contact portion, 22 Fourth contact portion, 23 Second source/drain region, 24 Second gate stack structure; 25 Dielectric sidewall, 26 First gate sidewall, 27 Semiconductor substrate, 28 Fin structure, 29 Mask structure, 30 First open slot, 31 Preformed structure, 32 First channel region, 33 Second open slot, 34 Second channel region, 35 Second gate sidewall, 36 Sacrificial gate, 37 Interlayer dielectric layer

### DETAILED DESCRIPTION OF EMBODIMENTS

Hereinafter, embodiments of the present disclosure will be described with reference to the accompanying drawings. It should be understood that these descriptions are only exemplary and are not intended to limit the scope of the present disclosure. In addition, in the following description, descriptions of well-known structures and technologies are omitted to avoid unnecessarily confusing the concept of the present disclosure.

Various structural diagrams according to embodiments of the present disclosure are shown in the drawings. These drawings are not drawn to scale, in which some details are exaggerated and may be omitted for clearer expression. The shapes of various regions and layers shown in the drawings as well as the relative sizes and positional relationships thereof are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is referred to as being “on” another layer/element, the layer/element may be directly on the another layer/element, or there may be an intervening layer/element therebetween. In addition, if one layer/element is “above” another layer/element in one orientation, the layer/element may be “below” the another layer/element when the orientation is reversed. In order to make the technical problems to be solved by the present disclosure, technical solutions and beneficial effects more clear, the present disclosure will be further explained in detail with the accompanying drawings and embodiments. It should be understood that the specific embodiments described here are only for explaining the present disclosure, and are not used to limit the present disclosure.

In addition, the terms “first” and “second” are only used for descriptive purposes, and may not be understood as indicating or implying relative importance or implicitly indicating the number of indicated technical features. Therefore, the features defined as “first” and “second” may explicitly or implicitly include one or more of these features. In the description of the present disclosure, the expression “plural” means two or more, unless otherwise specifically defined. The expression of “several” means one or more, unless otherwise specified.

In the description of the present disclosure, it should be noted that unless otherwise specified and limited, the terms “mounting”, “coupling” and “connection” should be broadly understood. For example, it may be a fixed connection, detachable connection or integrated connection; it may be a mechanical connection or an electrical connection; it may be a direct connection or an indirect connection through an intermediate medium; or it may be an internal communication between two elements or an interaction between two elements. Those skilled in the art may understand the specific meanings of the above terms in the present disclosure according to specific situations.

Interconnection technology of integrated circuits is a crucial and necessary part of packaging. Specifically, the interconnection technology of integrated circuits is a technology of connecting independent components in the same chip into a circuit module with certain functions in a certain manner, and is of high importance in advanced packaging. Chips are interconnected by packaging to receive power, exchange signals and finally perform operations. Since the speed, density and function of semiconductor products change according to the interconnection manner, the interconnection method is constantly changing and developing.

However, with the miniaturization of the device size, after the independent components in an existing semiconductor device are interconnected, the problem of signal line congestion is easy to occur, resulting in poor voltage drop and low working performance of the semiconductor device. Although those skilled in the art have developed a backside power supply network to improve the bottlenecks of power supply, signal lines and battery utilization by arranging power supply wiring on the back of a wafer, due to the small size of the device, there is an alignment accuracy problem when a buried power layer in direct electrical contact with the source/drain region included in the transistor is manufactured on the back side, and the buried power layer is easily shorted with the gate stack structure of the transistor, resulting in device failure, which is still not conducive to improving the working performance of the semiconductor device.

The objective of the present disclosure is to provide a semiconductor device and a manufacturing method thereof, so as to alleviate the problem of signal line congestion caused by device miniaturization, reduce voltage drop, and improve the working performance of the semiconductor device, which is beneficial to increasing the yield of the semiconductor device.

In order to solve the above technical problems, the embodiments of the present disclosure provide a semiconductor device and a manufacturing method thereof. In the semiconductor device provided by the embodiments of the present disclosure, the first source/drain region and at least part of the first gate stack structure included in the first layer semiconductor structure in the lower layer use a downward interconnection, and the second source/drain region and at least part of the second gate stack structure included in the second layer semiconductor structure in the upper layer use an upward interconnection, so that at least most of the interconnection contact structures of different layers may be separated along the thickness direction of the base substrate, and the problem of signal line congestion caused by device miniaturization may be alleviated.

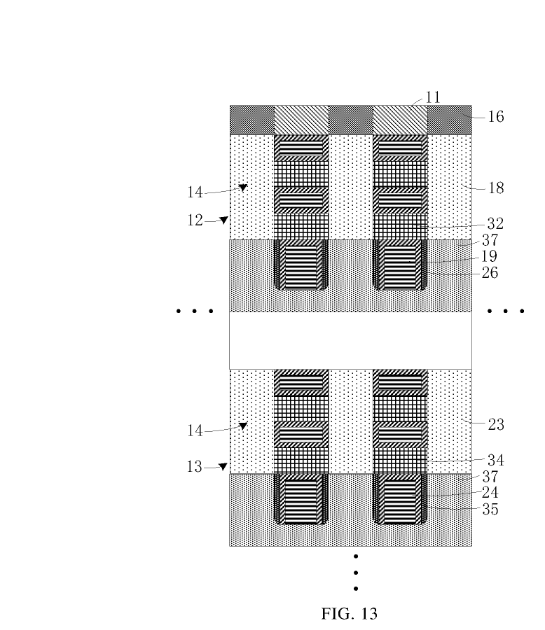

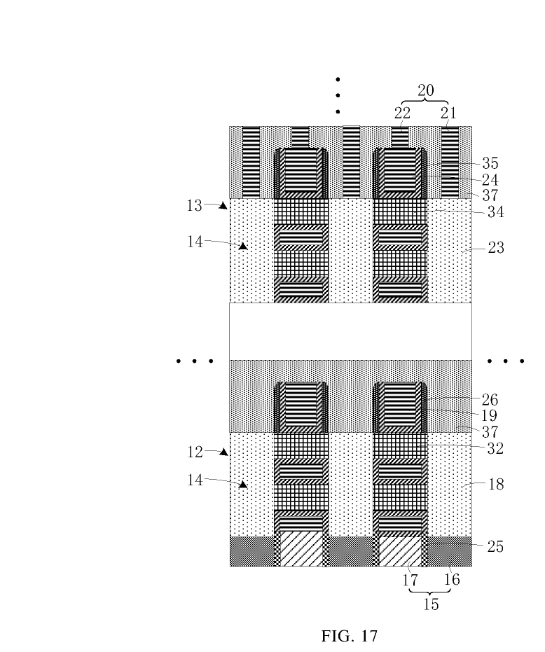

Specifically, in a first aspect, as shown in FIG. 13 and FIG. 17, the semiconductor device provided by the embodiments of the present disclosure includes: a base substrate 11, a first layer semiconductor structure 12, a second layer semiconductor structure 13, a first contact structure 15, and a second contact structure 20. The first layer semiconductor structure 12 is arranged on the base substrate 11. The second layer semiconductor structure 13 is arranged above the first layer semiconductor structure 12 at intervals along a thickness direction of the base substrate 11. The first layer semiconductor structure 12 and the second layer semiconductor structure 13 each include a plurality of transistors 14 distributed at intervals along a direction perpendicular to the thickness direction of the base substrate 11. The first contact structure 15 is arranged in the base substrate 11 and includes a first contact portion 16 in electrical contact with a first source/drain region included 18 in the transistor 14 in the first layer semiconductor structure 12 and a second contact portion 17 in electrical contact with a first gate stack structure 19 included in at least some of the transistors 14 in the first layer semiconductor structure 12. The first contact portion 16 and the second contact portion 17 are insulated from each other. The second contact structure 20 is arranged on a side of the second layer semiconductor structure 13 away from the first layer semiconductor structure 12 and includes a third contact portion 21 in electrical contact with a second source/drain region 23 included in the transistor 14 in the second layer semiconductor structure 13 and a fourth contact portion 22 in electrical contact with a second gate stack structure 24 included in at least some of the transistors 14 in the second layer semiconductor structure 13. The third contact portion 21 and the fourth contact portion 22 are insulated from each other.

With the above technical solution, as shown in FIG. 13 and FIG. 17, the semiconductor device provided by the embodiments of the present disclosure includes the first layer semiconductor structure 12 and the second layer semiconductor structure 13 which are distributed at intervals along the thickness direction of the base substrate 11, so as to improve the integration level of the semiconductor device and achieve further miniaturization of the semiconductor device. In addition, the first source/drain region 18 and at least part of the first gate stack structure 19 included in the first layer semiconductor structure 12 in a lower layer are respectively in electrical contact with the first contact portion 16 and the second contact portion 17 included in the first contact structure 15, and the first contact structure 15 is arranged below the first layer semiconductor structure 12. That is, the corresponding interconnection manner of the first source/drain region 18 and at least part of the first gate stack structure 19 in the first layer semiconductor structure 12 is a downward interconnection. Moreover, the second source/drain region 23 and at least some of the second gate stack structure 24 included in the second semiconductor structure in the upper layer are respectively in electrical contact with the third contact portion 21 and the fourth contact portion 22 included in the second contact structure 20, and the second contact structure 20 is arranged on the side of the second layer semiconductor structure 13 away from the first layer semiconductor structure 12. That is, the corresponding interconnection manner of the second source/drain region 23 and at least part of the second gate stack structure 24 in the second layer semiconductor structure 13 is an upward interconnection. In this case, compared with the existing backside power supply manner in which both adjacent two layer semiconductor structures use the upward interconnection or only the source/drain regions in the adjacent two layer semiconductor structures use the downward interconnection, in the semiconductor device provided by the embodiments of the present disclosure, the first source/drain region 18 and at least part of the first gate stack structure 19 included in the first layer semiconductor structure 12 in the lower layer use the downward interconnection, and the second source/drain region 23 and at least part of the second gate stack structure 24 included in the second semiconductor structure in the upper layer use the upward interconnection, so that at least most of the interconnection contact structures of different layers may be separated along the thickness direction of the base substrate 11, the problem of signal line congestion caused by device miniaturization may be alleviated, and meanwhile, it is also conducive to reducing the length of interconnection transmission path, reducing the voltage drop, and improving the working performance of the semiconductor device. In addition, the first contact portion 16 and the second contact portion 17 included in the first contact structure 15 are insulated from each other, and the third contact portion 21 and the fourth contact portion 22 included in the second contact structure 20 are insulated from each other, so as to prevent short circuit failure, which is beneficial to increasing the yield of semiconductor devices.

In the actual application process, the embodiments of the present disclosure do not specifically limit the structure and material of the base substrate, as long as it is applicable to the semiconductor device provided by the embodiments of the present disclosure. Exemplarily, the material of the base substrate may include insulating materials such as silicon oxide, silicon nitride or silicon oxynitride, so as to further reduce the risk of electric leakage of the first contact portion and the second contact portion in the first contact structure arranged in the base substrate.

Specifically, the base substrate may be a single-layered structure including only one material. Alternatively, the base substrate may also be a laminated structure including at least two materials, in which case the distribution of regions of different materials in the base substrate may be determined according to the specific manufacturing process of the base substrate, and is not specifically limited here. For example, regions of different materials in the base substrate may be stacked along the thickness direction of the base substrate.

For the above first layer semiconductor structure and the second layer semiconductor structure, the first layer semiconductor structure is located below the second layer semiconductor structure along the thickness direction of the base substrate, and the distance therebetween may be set according to actual requirements. In addition, the number and types of transistors included in the first layer semiconductor structure and the second layer semiconductor structure as well as the distribution of different transistors may be set according to actual application scenarios, as long as they are applicable to the semiconductor device provided by the embodiments of the present disclosure. Exemplarily, different transistors included in the first layer semiconductor structure and/or the second layer semiconductor structure may be fin field effect transistors and/or gate-all-around transistors. Specifically, for the same first layer semiconductor structure or the same second layer semiconductor structure, the device types of different transistors may be the same, for example, different transistors are all fin field effect transistors or gate-all-around transistors. Alternatively, the device types of different transistors may be different, for example, some transistors of different transistors are fin field effect transistors and the rest are gate-all-around transistors. The device types of transistors included in the first layer semiconductor structure and those included in the second layer semiconductor structure may be the same or different.

For a single transistor, as shown in FIG. 17, the transistor 14 in the first layer semiconductor structure 12 includes a first source/drain region 18, a first channel region 32 and a first gate stack structure 19. The first channel region 32 is located between the first source and drain regions 18, and both sides thereof along its own length direction are respectively in contact with the first source and drain regions 18. The first gate stack structure 19 is located at a periphery of the first channel region 32. Secondly, the transistor in the first layer semiconductor structure 12 may further include a first gate sidewall 26 at least located on both sides of the first gate stack structure 19 along its own length direction. In addition, in the case that the transistor 14 in the first layer semiconductor structure 12 is a gate-all-around transistor, the transistor 14 in the first layer semiconductor structure 12 may further include a first inner sidewall between the first gate stack structure 19 and the first source/drain region 18.

The materials of the first source/drain region and the first channel region may include any semiconductor material such as silicon, silicon germanium or germanium. The first gate stack structure may include a first gate dielectric layer and a first gate located at the periphery of the first channel region, and the material of the first gate dielectric layer may include insulating materials with high dielectric constant such as HfO₂, ZrO₂, TiO₂ or Al₂O₃. The material of the first gate may be a conductive material such as TiN, TaN or TiSiN. The materials of the first gate sidewall and the inner sidewall may include insulating materials such as SiO₂, SiN, SiCO or SiCON.

The transistor in the second layer semiconductor structure, as shown in FIG. 17, includes a second source/drain region 23, a second channel region 34 and a second gate stack structure 24. The second channel region 34 is located between the second source and drain regions 23, and both sides thereof along its own length direction are respectively in contact with the second source and drain regions 23. The second gate stack structure 24 is located at the periphery of the second channel region 34. Secondly, the transistor 14 in the second layer semiconductor structure 13 may further include a second gate sidewall 35 located at least on both sides of the second gate stack structure 24 along its own length direction. In addition, in the case that the transistor 14 in the second layer semiconductor structure 13 is a gate-all-around transistor, the transistor 14 in the second layer semiconductor structure 13 may further include a second inner sidewall located between the second gate stack structure 24 and the second source/drain region 23.

For the materials of the second source/drain region, the second channel region, the second gate stack structure, the second gate sidewall and the second inner sidewall, reference may be made to the materials of the first source/drain region, the first channel region, the first gate stack structure, the first gate sidewall and the first inner sidewall mentioned above, which are not described in detail here.

As for the first contact structure above, as shown in FIG. 17, the first contact structure 15 is arranged in the base substrate 11 to lead out the first source/drain region 18 and at least part of the first gate stack structure 19 in the first layer semiconductor structure 12 in the downward interconnection manner. Specifically, the first contact structure 15 includes a first contact portion 16 in electrical contact with the first source/drain region 18 and a second contact portion 17 in electrical contact with the first gate stack structure 19 included in at least some of the transistors 14. The material of the first contact portion 16 and/or the second contact portion 17 may include conductive materials such as copper, tungsten, silver or doped polysilicon. The material of the first contact portion 16 and that of the second contact portion 17 may be the same or different.

Secondly, the contact manner between the first contact portion and the first source/drain region is an interconnection through a Deep Trench Via (DTV for short). Alternatively, as shown in FIG. 17, the contact manner between the first contact portion 16 and the first source/drain region 18 may also be a direct backside contact, so as to further reduce the occupied area of the first contact structure 15 and further reduce the voltage drop. In addition, in this case, the first contact portion 16 may be in self-alignment with the first source/drain region 18, so as to reduce the risk of electric leakage and the difficulty of the subsequent interconnection process.

As for the second contact portion, the contact manner between the second contact portion and at least part of the first gate stack structure may be a manner of deep trench via or a direct backside contact. Secondly, different second contact portions may be respectively in electrical contact with all the first gate stack structures included in the first layer semiconductor structure. Alternatively, a part of the first gate stack structures in all the first gate stack structures are led out through the second contact portion in a manner of downward interconnection, while the rest of the first gate stack structures are led out through a fifth contact portion included in the second contact structure in a manner of upward interconnection.

In addition, the first contact portion and the second contact portion are insulated from each other, and specifically, they may be insulated from each other through a non-conductive base substrate. Alternatively, as shown in FIG. 17, the semiconductor device may further include a dielectric sidewall 25 located between the first contact portion 16 and the second contact portion 17, and the dielectric sidewall 25 is located below the first gate sidewall 26 of at least some of the transistors 14 in the first layer semiconductor structure 12. In this case, the first contact portion 16 and the second contact portion 17 may be electrically separated by the dielectric sidewall 25, and the dielectric sidewall 25 is located below the first gate side wall 26. At this time, along an arrangement direction of the first contact portion 16 and the second contact portion 17, the existence of the dielectric sidewall 25 will not occupy too much space for the formation of the first contact portion 16 and the second contact portion 17, thereby ensuring a larger lateral transmission area of the first contact portion 16 and the second contact portion 17.

Specifically, the material of the dielectric sidewall may include any insulating material such as silicon oxide, silicon nitride or silicon oxynitride. In addition, as shown in FIG. 17, an end portion of the first contact portion 16 away from the second layer semiconductor structure 13, an end portion of the second contact portion 17 away from the second layer semiconductor structure 13 and an end portion of the dielectric sidewall 25 away from the second layer semiconductor structure 13 may be aligned, so as to prevent a short circuit failure of the first contact portion 16 and the second contact portion 17 caused by incomplete removal of the second contact material on the first contact portion 16 and the dielectric sidewall 25 in the process of forming the second contact portion 17 after forming the first contact portion 16 and the dielectric sidewall 25, and ensure a high electrical reliability of the semiconductor device.

As for the second contact structure, as shown in FIG. 17, the second contact structure 20 is arranged on a side of the second layer semiconductor structure 13 away from the first layer semiconductor structure 12, so as to lead out the second source/drain region 23 and at least part of the second gate stack structure 24 in the second layer semiconductor structure 13 in a manner of upward interconnection. Specifically, the second contact structure 20 includes a third contact portion 21 in electrical contact with the second source/drain region 23 and a fourth contact portion 22 in electrical contact with at least part of the second gate stack structure 24. The embodiments of the present disclosure do not specifically limit the contact manner between the third contact portion 21 and the second source/drain region 23, and the contact manner between the fourth contact portion 22 and at least part of the second gate stack structure 24. For the materials of the third contact portion 21 and the fourth contact portion 22, reference may be made to the materials of the first contact portion 16 and the second contact portion 17 mentioned above, which will not be repeated here. In addition, the third contact portion 21 and the fourth contact portion 22 may be insulated from each other by an insulation structure such as an interlayer dielectric layer 37.

In a second aspect, the embodiments of the present disclosure provide a manufacturing method of a semiconductor device. Hereinafter, the manufacturing process will be described according to the sectional views of operations shown in FIGS. 1-17. Specifically, the manufacturing method of the semiconductor device includes steps as follows.

First, forming a first layer semiconductor structure and a base substrate are formed. The first layer semiconductor structure is arranged on the base substrate.

Then, a first contact structure is formed in the base substrate.

Next, a second layer semiconductor structure arranged above the first layer semiconductor structure at intervals along a thickness direction of the base substrate is formed. The first layer semiconductor structure and the second layer semiconductor structure each include a plurality of transistors distributed at intervals along a direction perpendicular to the thickness direction of the base substrate. The first contact structure includes a first contact portion in electrical contact with a first source/drain region included in the transistor in the first layer semiconductor structure and a second contact portion in electrical contact with a first gate stack structure included in at least some of the transistors in the first layer semiconductor structure. The first contact portion and the second contact portion are insulated from each other.

Subsequently, a second contact structure arranged on a side of the second layer semiconductor structure away from the first layer semiconductor structure is formed. The second contact structure includes a third contact portion in electrical contact with a second source/drain region included in the transistor in the second layer semiconductor structure and a fourth contact portion in electrical contact with a second gate stack structure included in at least some of the transistors in the second layer semiconductor structure. The third contact portion and the fourth contact portion are insulated from each other.

For the beneficial effects of the second aspect in the embodiments of the present disclosure and various implementations thereof, reference may be made to the beneficial effect analysis of the first aspect and various implementations thereof, which will not be repeated here.

Specifically, the structure of the semiconductor device manufactured in the second aspect in the embodiments of the present disclosure is the same as the structure of the semiconductor device provided in the first aspect above. On this basis, for the specific structures and materials of the first layer semiconductor structure, the base substrate, the first contact structure, the second layer semiconductor structure and the second contact structure in the semiconductor device manufactured in the second aspect, reference may be made to the above text, which will not be repeated here.

Exemplarily, the above step of forming the first layer semiconductor structure may include steps as follows. First, a semiconductor substrate is provided. The semiconductor substrate may be a substrate of any semiconductor material such as a silicon substrate, a silicon-on-insulator substrate, a germanium silicon substrate or a germanium substrate.

Next, a plurality of fin structures distributed at intervals along a direction perpendicular to the thickness direction of the base substrate are formed on the semiconductor substrate, and a mask structure spanning across the fin structures is formed.

Specifically, the specific manufacturing process of the above fin structures may be determined according to the device types of transistors included in the first layer semiconductor structure. For example, if the transistors included in the first layer semiconductor structure are fin field effect transistors, the semiconductor substrate may be directly etched by processes such as photolithography and etching to obtain fins. Then, a shallow trench isolation structure is formed by processes such as deposition, in which the portion of the fin exposed outside the shallow trench isolation structure is a fin structure. Alternatively, a semiconductor layer may be formed on the semiconductor substrate by processes such as epitaxy, and then the semiconductor layer and a part of the semiconductor substrate may be etched by processes such as photolithography and etching to obtain fins. Next, the shallow trench isolation structure is formed by processes such as deposition (the height of the top of the shallow trench isolation structure is less than or equal to the height of the bottom of the semiconductor layer), in which the portion of the fin exposed outside the shallow trench isolation structure is a fin structure.

For another example, in the case that the transistors included in the first layer semiconductor structure are gate-all-around transistors, a sacrificial layer and a channel layer which are alternately stacked may be formed on the semiconductor substrate by processes such as epitaxy. In the sacrificial layer and the channel layer which are alternately stacked, a film layer located at the bottom layer is the sacrificial layer. Then, the sacrificial layer and the channel layer which are alternately stacked and a part of the semiconductor substrate are etched by processes such as photolithography and etching to obtain fins. Next, the shallow trench isolation structure is formed by processes such as deposition (the height of the top of the shallow trench isolation structure is less than or equal to the height of the bottom of the semiconductor layer), in which the portion of the fin exposed outside the shallow trench isolation structure is a fin structure.

After the fin structures are formed, the mask structure may be formed by processes such as deposition and etching. The embodiments of the present disclosure do not specifically limit the specific structure and material of the mask structure. For example, the mask structure may include a sacrificial gate. For another example, as shown in parts (1) and (2) of FIG. 1, the mask structure 29 may include a sacrificial gate 36 and a first gate sidewall 26 located on both sides of the sacrificial gate 36 along the length direction.

Next, as shown in parts (1) and (2) of FIG. 1, a portion of each fin structure 28 exposed outside the mask structure 29 may be selectively removed by processes such as wet etching or dry etching.

Subsequently, as shown in parts (1) and (2) of FIG. 2, under a protective effect of the mask structure 29, a part of the semiconductor substrate 27 is selectively etched to form a first open slot 30. As shown in parts (1) and (2) of FIG. 3, a preformed structure 31 filled in the first open slot 30 is formed. The material of the preformed structure 31 and the material of the semiconductor substrate 27 are different.

Specifically, the first open slot is used to fill and form the first contact portion, and the preformed structure acts as a reserved space. At least after the first semiconductor structure is formed, the first open slot may be released by selectively removing the preformed structure, so as to prevent a direct formation of the first contact portion first, which may affect the formation of other structures and the formation quality of the first contact portion. The material of the above preformed structure may include dielectric material or semiconductor material, as long as it is different from the material of the semiconductor substrate. Exemplarily, the material of the preformed structure may include at least one of silicon nitride, silicon oxynitride or amorphous carbon.

Afterwards, as shown in parts (1) and (2) of FIG. 4, the first source/drain region 18 may be formed above the preformed structure 31 by processes such as epitaxy.

Next, as shown in parts (1) and (2) of FIG. 5, an interlayer dielectric layer 37 may be formed on the semiconductor substrate 27 by processes such as deposition and chemical mechanical polishing, and a top portion of the interlayer dielectric layer 37 is flush with a top portion of the mask structure 29. The material of the interlayer dielectric layer 37 may include insulating materials such as silicon oxide or silicon nitride.

Then, as shown in parts (1) and (2) of FIG. 6, a first channel region 32 included in the transistor in the first layer semiconductor structure is formed based on rest of the fin structures. As shown in parts (1) and (2) of FIG. 7, the first gate stack structure 19 is formed at a periphery of the first channel region 32.

Specifically, the specific process of forming the first channel region and the first gate stack structure may be determined according to the device types of transistors included in the first layer semiconductor structure, and is not specifically limited here.

For example, in the case that the transistors included in the first layer semiconductor structure are fin field effect transistors, at least part of the mask structure may be selectively removed by processes such as wet etching or dry etching. At this time, the rest of the fin structures form the first channel region. Then, the first gate stack structure is formed by processes such as atomic layer deposition.

For another example, in the case that the transistors included in the first layer semiconductor structure are gate-all-around transistors, at least part of the mask structure may be selectively removed by processes such as wet etching or dry etching, and the rest of the sacrificial layer may be removed. At this time, the rest of the channel layer forms the first channel region. Then, the first gate stack structure is formed by processes such as atomic layer deposition.

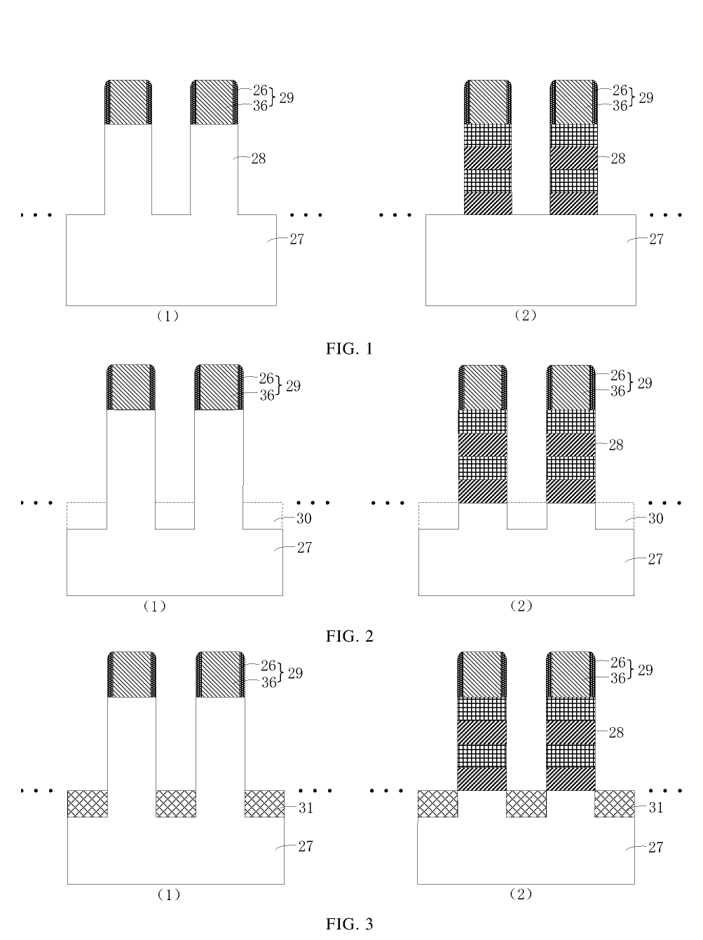

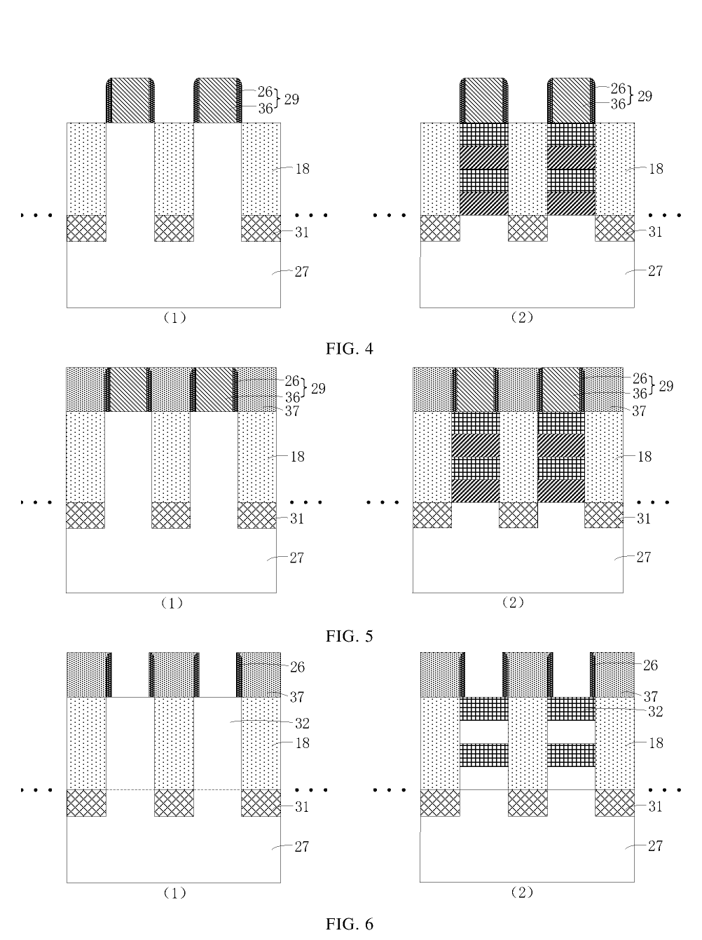

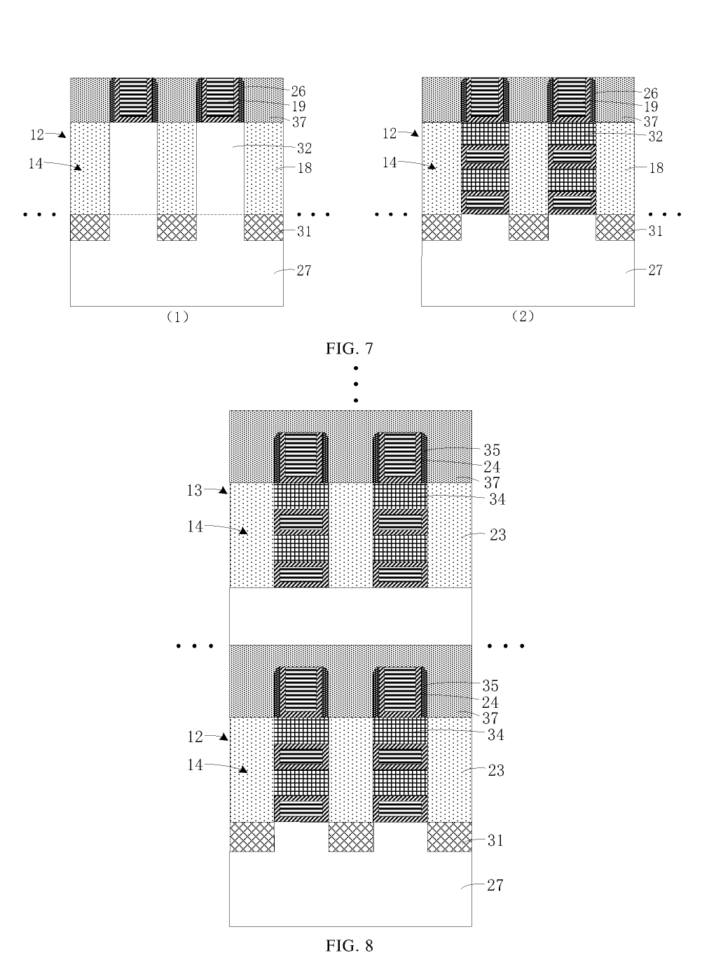

As shown in parts (1) and (2) of FIG. 8, after the above first semiconductor structure 12 is formed, the second layer semiconductor structure 13 may be formed first. For the specific manufacturing process of the second layer semiconductor structure 13, reference may be made to the manufacturing process of the first layer semiconductor structure 12 above, which will not be repeated here. The difference is that it is not necessary to form the first open slot and the preformed structure when manufacturing the second layer semiconductor structure 13. Then, the base substrate is formed, and the first contact structure is formed in the base substrate.

Alternatively, before the second layer semiconductor structure is formed, the base substrate may be formed, and the first contact structure is formed in the base substrate. The specific formation sequence of the base substrate and the first contact structure may be determined according to actual needs, and is not specifically limited here.

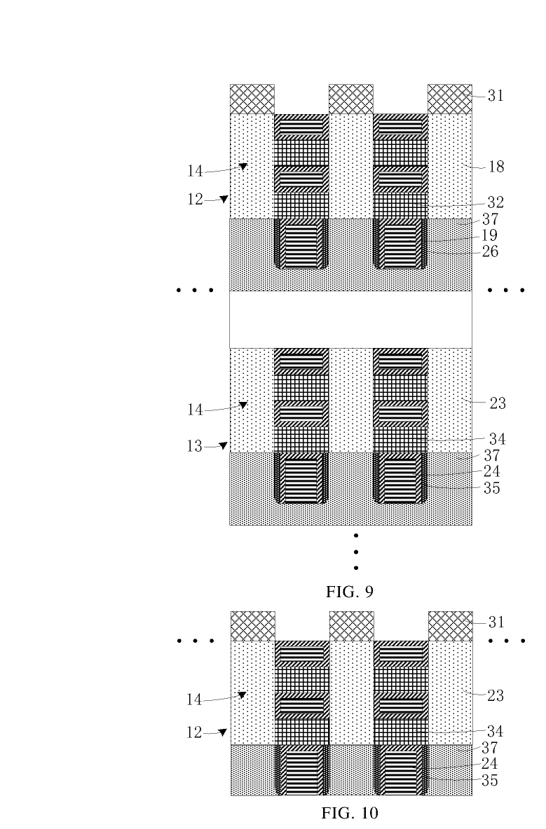

Exemplarily, the base substrate and the first contact structure may be formed in the steps as follows. As shown in parts (1) and (2) of FIG. 9 and FIG. 10, the semiconductor substrate may be selectively removed by processes as wet etching or dry etching. At this time, since the materials of the preformed structure 31 and the semiconductor substrate are different, the preformed structure 31 will remain after the semiconductor substrate is removed.

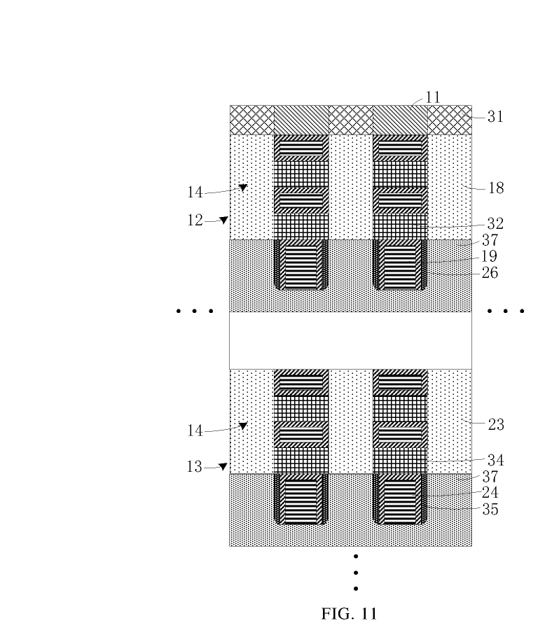

Subsequently, as shown in parts (1) and (2) of FIG. 11, the base substrate 11 may be formed on the side of the first layer semiconductor structure 12 away from the second layer semiconductor structure 13 by processes such as deposition and chemical mechanical polishing. The base substrate 11 is flush with the side of the preformed structure 31 away from the first layer semiconductor structure 12, and the materials of the base substrate 11 and the preformed structure 31 are different. Specifically, for the material and structure of the base substrate 11, reference may be made to the above text. The base substrate 11 is flush with the side of the preformed structure 31 away from the first layer semiconductor structure 12, so that the preformed structure 31 may be exposed to facilitate the subsequent selective removal of the preformed structure 31.

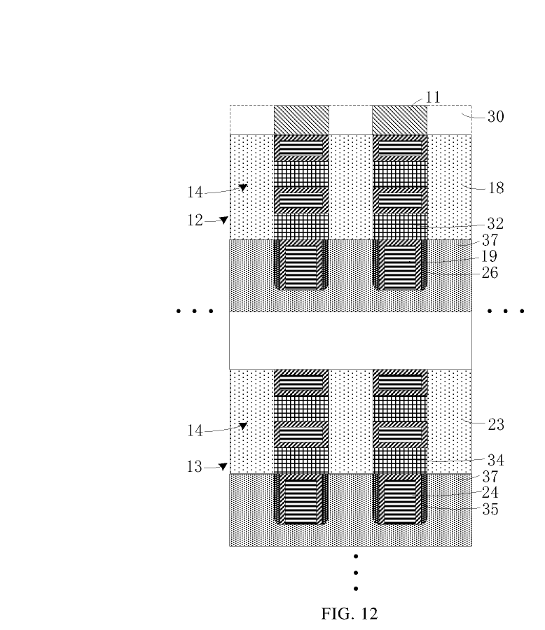

Next, as shown in parts (1) and (2) of FIG. 12, the preformed structure may be selectively removed by processes such as wet etching or dry etching. At this time, the first open slot 30 is released. Then, as shown in parts (1) and (2) of FIG. 13, the first contact portion 16 may be formed in the first open slot by processes such as sputtering or evaporation.

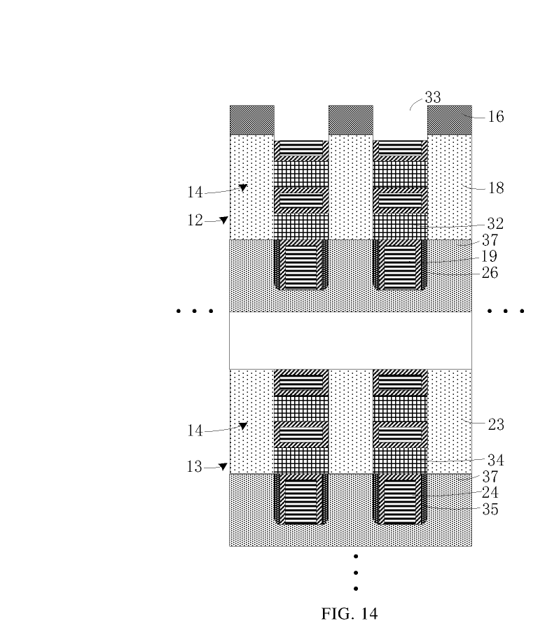

Then, as shown in parts (1) and (2) of FIG. 14, a portion of the base substrate 11 below the first gate stack structure 19 may be selectively removed by processes such as wet etching or dry etching to form a second open slot 33. The second open slot 33 is at least used to fill the second contact portion.

It should be noted that in the process of forming the second open slot, only the portion of the base substrate below the first gate stack structure may be removed. Alternatively, as shown in parts (1) and (2) of FIG. 14, a portion of the first gate dielectric layer in contact with the base substrate 11 may also be removed at the same time, so that the second contact portion formed subsequently may be in direct electrical contact with the first gate to reduce the contact resistance.

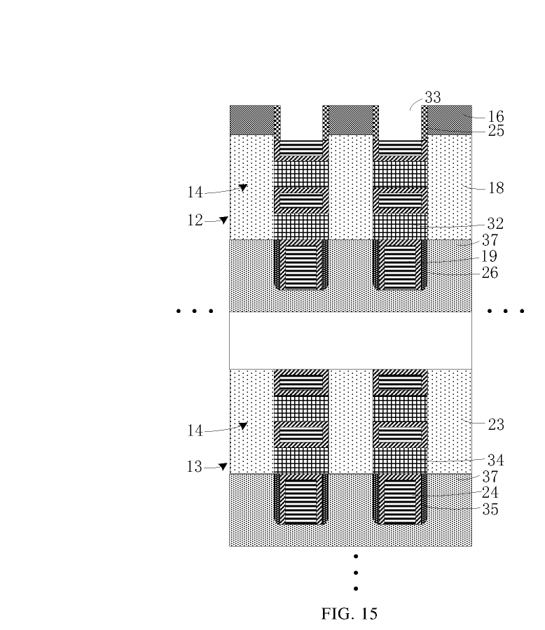

Subsequently, as shown in parts (1) and (2) of FIG. 15, a dielectric sidewall 25 at least covering a side wall of the first contact portion 16 may be formed in the second open slot 33 and along the length direction of the first gate stack structure 19 by processes such as deposition and etching. For the material of the dielectric sidewall 25, reference may be made to the above text.

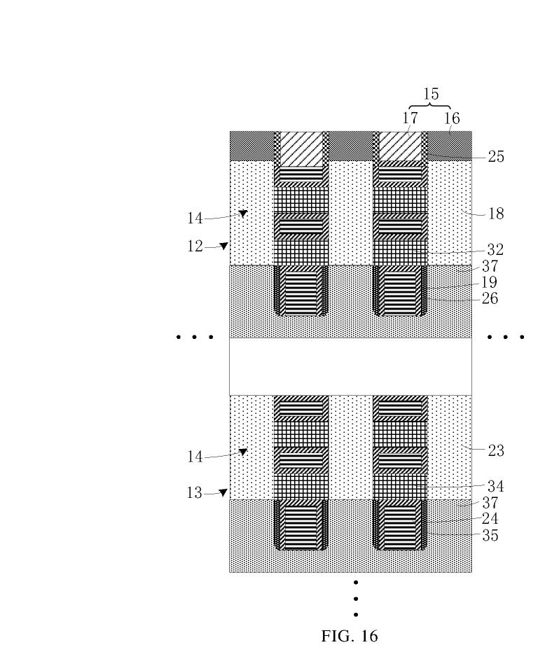

Next, as shown in parts (1) and (2) of FIG. 16, the second contact portion 17 may be formed in the rest of the second open slot by processes such as sputtering or evaporation to obtain the first contact structure 15.

It should be noted that if the first contact portion and the second contact portion are separated by the base substrate, the above manufacturing process of the dielectric sidewall may not be performed.

As for the manufacturing process of the second contact structure, as shown in parts (1) and (2) of FIG. 17, an interlayer dielectric layer 37 may be first formed on the side of the second layer semiconductor structure 13 away from the base substrate by processes such as deposition. Then, a contact hole is formed by processes such as etching. The third contact portion 21 and the fourth contact portion 22 filled in the contact hole are formed by processes such as sputtering or evaporation to obtain the second contact structure 20.

It should be noted that the second contact structure and the second layer semiconductor structure above may be formed in various manners. Since how to form the above structures is not the main feature of the present disclosure, it is only briefly introduced in the present specification, so that those of ordinary skills in the art may easily implement the present disclosure. Those of ordinary skills in the art may design other manners to manufacture the second contact structure and the second layer semiconductor structure above.

In the above description, the technical details such as patterning and etching of each layer are not explained in detail. However, those skilled in the art should understand that layers, regions etc. with a desired shape may be formed by various technical means. In addition, in order to form the same structure, those skilled in the art may also design methods that are not exactly the same as those described above. In addition, although various embodiments have been described separately above, this does not mean that the measures in various embodiments may not be advantageously used in combination.

The embodiments of the present disclosure have been described above. However, these embodiments are only for clearer explanation, and are not intended to limit the scope of the present disclosure. The scope of the present disclosure is defined by the appended claims and the equivalents thereof. Without departing from the scope of the present disclosure, those skilled in the art may make various substitutions and modifications, and these substitutions and modifications should all fall within the scope of the present disclosure.

What is claimed is:

1. A semiconductor device, comprising:
a base substrate,
a first layer semiconductor structure arranged on the base substrate;
a second layer semiconductor structure arranged above the first layer semiconductor structure at intervals along a thickness direction of the base substrate, wherein the first layer semiconductor structure and the second layer semiconductor structure each include a plurality of transistors distributed at intervals along a direction perpendicular to the thickness direction of the base substrate;
a first contact structure arranged in the base substrate and comprising a first contact portion in electrical contact with a first source/drain region comprised in the transistor in the first layer semiconductor structure and a second contact portion in electrical contact with a first gate stack structure comprised in at least some of the transistors in the first layer semiconductor structure, wherein the first contact portion and the second contact portion are insulated from each other; and
a second contact structure arranged on a side of the second layer semiconductor structure away from the first layer semiconductor structure and comprising a third contact portion in electrical contact with a second source/drain region comprised in the transistor in the second layer semiconductor structure and a fourth contact portion in electrical contact with a second gate stack structure comprised in at least some of the transistors in the second layer semiconductor structure, wherein the third contact portion and the fourth contact portion are insulated from each other.

2. The semiconductor device according to claim 1, wherein a contact manner between the first contact portion and the first source/drain region is a direct backside contact; and/or
the contact manner between the second contact portion and at least part of the first gate stack structure is the direct backside contact.

3. The semiconductor device according to claim 1, wherein the first contact portion is in self-alignment with the first source/drain region.

4. The semiconductor device according to claim 1, wherein the semiconductor device further comprises a dielectric sidewall located between the first contact portion and the second contact portion, and located below a first gate sidewall of at least some of the transistors in the first layer semiconductor structure.

5. The semiconductor device according to claim 4, wherein an end portion of the first contact portion away from the second layer semiconductor structure, an end portion of the second contact portion away from the second layer semiconductor structure and an end portion of the dielectric sidewall away from the second layer semiconductor structure are aligned.

6. A manufacturing method of a semiconductor device, comprising:
forming a first layer semiconductor structure and a base substrate, wherein the first layer semiconductor structure is arranged on the base substrate;
forming a first contact structure in the base substrate;
forming a second layer semiconductor structure arranged above the first layer semiconductor structure at intervals along a thickness direction of the base substrate, wherein the first layer semiconductor structure and the second layer semiconductor structure each include a plurality of transistors distributed at intervals along a direction perpendicular to the thickness direction of the base substrate, the first contact structure comprises a first contact portion in electrical contact with a first source/drain region comprised in the transistor in the first layer semiconductor structure and a second contact portion in electrical contact with a first gate stack structure comprised in at least some of the transistors in the first layer semiconductor structure, and the first contact portion and the second contact portion are insulated from each other; and
forming a second contact structure arranged on a side of the second layer semiconductor structure away from the first layer semiconductor structure, wherein the second contact structure comprises a third contact portion in electrical contact with a second source/drain region comprised in the transistor in the second layer semiconductor structure and a fourth contact portion in electrical contact with a second gate stack structure comprised in at least some of the transistors in the second layer semiconductor structure, and the third contact portion and the fourth contact portion are insulated from each other.

7. The manufacturing method of a semiconductor device according to claim 6, wherein the forming a first layer semiconductor structure comprises:
providing a semiconductor substrate;
forming a plurality of fin structures distributed at intervals along the direction perpendicular to the thickness direction of the base substrate on the semiconductor substrate, and a mask structure spanning across the fin structures;
selectively removing a portion of each of the fin structures exposed outside the mask structure;
selectively etching, under a protective effect of the mask structure, a part of the semiconductor substrate to form a first open slot and a preformed structure filled in the first open slot, wherein a material of the preformed structure is different from a material of the semiconductor substrate;
forming the first source/drain region above the preformed structure; and
forming, based on rest of the fin structures, a first channel region comprised in the transistor in the first layer semiconductor structure and the first gate stack structure on a periphery of the first channel region.

8. The manufacturing method of a semiconductor device according to claim 7, wherein the forming a base substrate and a first contact structure comprises:
selectively removing the semiconductor substrate;
forming the base substrate on a side of the first layer semiconductor structure away from the second layer semiconductor structure, wherein the base substrate is flush with a side of the preformed structure away from the first layer semiconductor structure, and a material of the base substrate is different from a material of the preformed structure;
selectively removing the preformed structure, and forming the first contact portion in the first open slot;
selectively removing a portion of the base substrate below the first gate stack structure to form a second open slot; and
forming a dielectric sidewall at least covering a side wall of the first contact portion in the second open slot and along a length direction of the first gate stack structure, and the second contact portion in rest of the second open slot to obtain the first contact structure.

9. The manufacturing method of a semiconductor device according to claim 7, wherein the material of the preformed structure comprises at least one of silicon nitride, silicon oxynitride or amorphous carbon.

10. The manufacturing method of a semiconductor device according to claim 6, wherein after the second layer semiconductor structure arranged above the first layer semiconductor structure at intervals is formed along the thickness direction of the base substrate, the base substrate is formed, and the first contact structure is formed in the base substrate.
